(19) United States
(12) Patent Application Publication
(10) Pub. No.: US 2012/0052677 A1
(43) Pub. Date: Mar. 1, 2012

(54) Method for Forming Lead-Free Solder Balls with a Stable Oxide Layer Based on a Plasma Process

(75) Inventors: Soeren Zenner, Dresden (DE); Gotthard Jungnickel, Radeberg (DE); Frank Kuechenmeister, Dresden (DE)

(73) Assignee: GLOBALFOUNDRIES INC., Grand Cayman (KY)

(21) Appl. No.: 13/185,154

(22) Filed: Jul. 18, 2011

(30) Foreign Application Priority Data
Aug. 31, 2010 (DE) 10 2010 040 063.7

(51) Int. Cl. H01L 21/283

(52) U.S. Cl. 438/613; 257/E21.159

(57) ABSTRACT

Solder balls of semiconductor devices and, in particular, lead-free solder balls receive a very uniform passivation layer, for instance in the form of an oxide layer, which is formed by applying a plasma treatment. For example, the passivation layer may be provided with a thickness of 5-50 nm which may thus allow, due to the superior uniformity, a reliable protection of the solder balls while nevertheless ensuring a reliable removal during the final solder process.

### BACKGROUND OF THE INVENTION

1. Field of the Invention

The present disclosure generally relates to semiconductor devices comprising lead-free solder balls for directly attaching an appropriately formed package or carrier substrate to a die.

2. Description of the Related Art

In manufacturing integrated circuits, it is usually necessary to package a chip and provide leads and terminals for connecting the chip circuitry with the periphery. In some packaging techniques, chips, chip packages or other appropriate units may be connected by means of solder balls, formed from so-called solder bumps or bumps, which in turn are formed on metal regions of the metallization system of at least one of the units, for instance in the metallization system of the microelectronic chip. In order to connect the micro-electronic chip with the corresponding carrier, the surfaces of the two respective units to be connected, i.e., a microelectronic chip comprising, for instance, one or more integrated circuits, and a corresponding package, have formed thereon adequate pad arrangements to electrically connect the two units after reflowing the solder balls provided at least on one of the units, for instance on the microelectronic chip. In other techniques, solder balls may have to be formed that are to be connected to corresponding wires, or the solder balls may be brought into contact with corresponding pad areas of another substrate acting as a heat sink. Consequently, it may be necessary to form a large number of solder balls that may be distributed over the entire chip area, thereby providing, for example, the I/O capability required for modern microelectronic chips that usually include complex circuitry, such as microprocessors, storage circuits and the like, and/or include a plurality of integrated circuits forming a complete complex circuit system.

In order to provide hundreds or thousands of mechanically well-fastened solder balls on corresponding pads, the attachment procedure of the solder balls requires a careful design since the entire device may be rendered useless upon failure of only one of the solder balls. For this reason, one or more specific metal layers are generally placed between the bumps, from which the solder balls are formed by reflowing, and the underlying substrate or wafer including the pad arrangement.

The size of the solder balls is a critical parameter during the further processing of the semiconductor device, since a reliable inter-metallic connection upon connecting a package substrate having a complementary pad arrangement formed thereon with the solder balls may critically depend on an appropriate contact of the solder ball and the associated solder pad of the package substrate. Thus, the one or more metal layers formed beneath the solder bumps, usually referred to as under-bump metallization, may provide superior process uniformity, for instance with respect to depositing the solder material by electroplating techniques, which is presently the preferred deposition technique for solder materials since physical vapor deposition of solder bump material, which is also frequently used in the art, requires a complex masking strategy in order to avoid any misalignments due to thermal expansion of the mask while it is contacted by the hot metal vapors. During the electroplating deposition technique, also a mask is used, however, contrary to any vapor phase deposition techniques, the mask is created by using photolithography for patterning any appropriate material which, after the deposition of the solder material, may be efficiently removed without unduly affecting the solder material. Thus, on the basis of the continuous under-bump metallization, the solder material is deposited into corresponding openings formed in the mask material, such as a photoresist mask, which is then removed, followed by a patterning process for removing any exposed portions of the under-bump metallization material. while using the solder bumps as efficient etch mask. Consequently, during the corresponding patterning process, well-defined islands are formed below the solder material, thereby providing appropriate wetting layers for the subsequent reflow process during which the solder bumps are shaped into spheres or balls. As indicated above, the size and thus the height of these solder balls is critical for the actual attachment of the chip to the package substrate, since any variations in height may lead to a reduced contact in the final reflow process for connecting to the associated solder pads of the package substrate. During the reflowing of the solder material for forming the solder balls, especially any tin content therein, may form an inter-metallic phase with the under-bump metallization layer, thereby creating a reliable metal interface. Moreover, during the reflow process, an oxide layer comprised of tin and other components, such as lead and the like, is formed on the surface of the solder balls and imparts a shiny appearance to the solder balls. The oxide layer acts as a passivation layer during the subsequent manufacturing processes, i.e., the dicing of the substrate, substrate transportation and the like, which may involve moderately long storage times, wherein nevertheless the integrity of the solder balls is to be preserved so as to substantially avoid any additional non-uniformities of the solder balls. Hence, the oxide layer desirably exhibits a high stability during the further manufacturing processes, while on the other hand the oxide layer should be readily removable by a flux material that is provided prior to and during the final solder process for attaching the semiconductor chip to the package substrate. During the removal of the oxide layer by the flux material, however, any non-removed residuals of the oxide may significantly affect the solder process, which may result in a non-wet contact with the solder pad of the package substrate. In this case, a less reliable connection or a total contact failure may result. Consequently, the overall production yield in this very late manufacturing stage may significantly depend on the uniformity of the solder balls and thus on the uniformity and removability of the oxide layer formed thereon, since even a less reliable connection or the failure of a single solder ball may result in a total failure of the entire semiconductor device. For this reason, in well-established manufacturing strategies using solder materials on the basis of lead, frequently a re-oxidation process is implemented immediately after the reflow process in order to provide superior uniformity of the resulting oxide layer, while also adjusting the thickness of the oxide layer in such a manner that a reliable removal during the final solder process on the basis of the flux material is accomplished. In recent developments, however, solder materials having incorporated therein a certain amount of lead may be increasingly avoided, for instance due to environmental issues associated with the lead material. Moreover, lead material may also be a source of “soft” errors of the semiconductor device during operation, for instance by radioactive decay of non-stable isotopes, which may frequently be contained in the lead material. Hence, lead-free solder materials are increasingly used in the bump technology, for instance in the form of tin and silver-containing bump materials, tin and copper-containing bump materials and the like. It should be appreciated that, in this context, a “lead-free” solder material is to be understood as any metal-containing solder material having a melting temperature of approximately 300° C. and less, while a fraction of any lead material, which may be incorporated by unintentional imperfections during the manufacturing process and the like, may be 0.1 weight percent or significantly less. During a lead-free manufacturing process for providing solder balls, basically the same process steps may be applied, as described above, wherein, however, upon reflowing the solder bumps for forming the solder balls, corresponding increased temperatures may have to be applied since typically the reflow temperature of lead-free solder materials, such as Sn/Ag (tin/silver), are higher compared to lead-containing solder materials. Also in this reflow process, an oxide layer may form on surface areas of the solder balls, which may thus act as a passivation layer, as discussed above. Although the oxide layer may preserve integrity of the solder balls during the further processing, as is also discussed above, it turns out, however, that any non-uniformities of the oxide material may result in significant yield losses. On the other hand, a well-controlled thermal re-oxidation process applied immediately after the reflow process, as described above, is difficult for the lead-free solder materials since the process temperature required for superior control of the thermal oxidation process is above the melting temperature of the lead-free solder material.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and strategies in which lead-free solder materials may be efficiently passivated by forming a passivation layer of well-controlled thickness and uniformity after the reflow process for forming the solder balls. To this end, a plasma-based process may be applied in order to treat any exposed surface areas of the solder balls, thereby avoiding any elevated process temperatures. In some illustrative embodiments disclosed herein, the plasma-based surface treatment may be performed on the basis of an oxygen plasma, which may result in the formation of an oxide layer of superior uniformity, wherein a thickness of the oxide layer may be determined on the basis of controlling at least one process parameter of the plasma treatment. In this manner, a wide variety of lead-free solder materials may be treated, such as solder materials containing tin and silver, solder materials containing tin and copper and the like, so that the resulting passivation layer may provide superior integrity during further manufacturing processes to be performed after the reflow process for forming the solder balls, while at the same time enabling an efficient removal of the passivation layer during the final solder process by using well-established flux materials.

One illustrative method disclosed herein comprises forming a plurality of solder bumps above a substrate and forming solder balls by reflowing the plurality of solder bumps. Moreover, the method comprises forming an oxide layer on exposed surface areas of the solder balls by exposing the solder balls to an oxygen-containing plasma atmosphere.

A further illustrative method disclosed herein relates to passivating lead-free solder balls in a semiconductor device. The method comprises providing a plurality of the lead-free solder balls so as to have an exposed surface area. The method further comprises forming a passivation layer on the exposed surface area with a thickness of approximately 50 nm or less by performing a plasma treatment using an oxygen-containing plasma atmosphere.

A further illustrative method disclosed herein comprises forming a plurality of contact elements in a metallization system of a semiconductor device on the basis of lead-free materials, wherein the contact elements are configured to connect to a package substrate. The method further comprises forming a passivation layer on any exposed surface areas of the contact elements by exposing the contact elements to a plasma atmosphere. Additionally, the method comprises connecting each of the contact elements, which include the passivation layer, to a contact structure formed on the package substrate by reflowing at least a portion of the contact elements.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device in an advanced manufacturing stage in which a bump structure may be provided as a part of a metallization system, wherein, in some illustrative embodiments, a lead-free solder material may be used for forming solder bumps or contact elements comprising a lead-free solder bump material, according to illustrative embodiments;

FIG. 1b schematically illustrates a cross-sectional view of the semiconductor device during a reflow process for forming solder balls on the basis of the solder material of the contact elements or solder bumps, according to illustrative embodiments;

FIG. 1c schematically illustrates a cross-sectional view of the semiconductor device in a process phase after the reflow process, wherein a plasma treatment may be performed so as to condition any exposed surface areas of the solder balls or contact elements for forming a desired passivation layer, according to illustrative embodiments;

FIG. 1d schematically illustrates a cross-sectional view of the semiconductor device in a further advanced manufacturing stage in which, alternatively or in addition to the preceding plasma process, a further plasma atmosphere is established in order to form a reliable passivation layer with a well-controllable thickness and uniformity, according to illustrative embodiments; and

FIG. 1e schematically illustrates the semiconductor device in a further advanced manufacturing stage in which a solder process may be performed so as to connect the semiconductor chip with a package substrate, while at the same time reliably removing the passivation layer on the basis of a flux material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of increased yield loss observed, in particular, during the processing of lead-free solder balls upon connecting semiconductor chips or dies with a package or carrier substrate. To this end, the present disclosure provides manufacturing techniques for forming a reliable yet readily removable passivation layer on solder balls, in particular on lead-free solder balls, in order to preserve integrity of the solder balls during the further manufacturing processes, such as substrate transport, substrate storage, dicing of the substrates and the like, while at the same time enabling an efficient removal of the passivation layer prior to or during the solder process for connecting the semiconductor chip with a corresponding carrier or package substrate. For this purpose, defined process conditions may be established on the basis of a plasma ambient in order to avoid extremely high temperatures, while nevertheless providing superior conditions for forming the passivation layer with a desired thickness and uniformity, as required for preserving integrity of the solder balls during the further processing. The superior uniformity of the passivation layer, which in some illustrative embodiments is an oxide layer, may be accomplished by establishing well-defined process conditions during the reflowing of the solder material when forming solder balls. To this end, an appropriate process atmosphere may be established, such as an inert ambient, for example on the basis of hydrogen, hydrogen and nitrogen, and the like, in order to avoid undue surface reactions, for instance avoiding any uncontrolled oxidation processes upon reflowing the bump material. It should be appreciated that the term “inert process atmosphere” as used herein should be understood in the sense that, in particular, the oxygen contents of the process atmosphere may be significantly less compared to any other “inert” gas components, such as hydrogen, nitrogen and the like, although the presence of minute amounts of oxygen may still be observable in the inert process atmosphere due to unavoidable imperfections of material resources and process tools, wherein a fraction of 0.1 volume percent oxygen with respect to any other gas component may be considered as an inert process atmosphere thereinafter. Typically, the fraction of oxygen may be even further reduced, depending on the available process tools and the quality of the process gases, such as nitrogen, hydrogen and the like. Consequently, by using a well-defined process atmosphere during the reflow process, any non-controllable surface treatments, in particular an oxidation, may be substantially avoided so that well-defined surface conditions may be encountered during the further processing of the solder balls. Thereafter, in some illustrative embodiments disclosed herein, the surface state of the solder balls may be appropriately conditioned by using appropriate plasma ambient, for instance based on argon and the like, in order to remove any surface irregularities, such as oxide residues and the like. In this case, even a moderately “imperfect” inert process atmosphere during the reflow process for forming the solder balls may result in substantially uniform surface conditions of the solder balls during the subsequent formation of an appropriate passivation layer of superior uniformity. In some illustrative embodiments, a further plasma treatment may be performed so as to initiate a chemical reaction at appropriate temperatures, for instance in the range of room temperature to approximately 250° C., which may be below the flow temperature of the solder material under consideration. In some illustrative embodiments, the plasma treatment may be based on an oxygen plasma, thereby initiating an oxidation process, wherein the process parameters may be appropriately controlled so as to obtain a desired layer thickness with a high degree of uniformity, i.e., the layer thickness may vary by less than approximately ten percent with respect to an average thickness value obtained across the entire surface of the solder ball. Furthermore, the thickness may vary by less than approximately 10 percent across the entire semiconductor device, which may thus provide superior process conditions during a final solder process when the solder balls are connected with a corresponding package or carrier substrate.

In other illustrative embodiments disclosed herein, the surface of the solder balls may be treated with a plasma atmosphere, such as oxygen plasma, without requiring a preceding “conditioning” process, thereby also forming a passivation layer of appropriate thickness and with high uniformity. For example, on the basis of the principles disclosed herein, a wide variety of solder materials may be processed so as to obtain a desired passivation layer, such as lead-containing solder materials, wherein a high temperature thermal oxidation process may be omitted and may be replaced by one or more plasma treatments. In preferred embodiments, the solder balls or contact elements may be provided by using a lead-free solder material, such as Sn/Ag, Silicon nitride/Cu and the like, wherein the composition of any such lead-free solder materials may also vary, depending on process and device requirements. On the basis of the plasma treatment, an effective passivation layer may be formed for any of these lead-free solder materials, which may comprise a significant amount of tin by appropriately adapting the process parameters, as will be described later on in more detail. For example, in particular at or near the eutectic composition of these solder materials, reliable and yet readily removable passivation layers in the form of oxide layers may be obtained on the basis of the principles disclosed herein. For example, a layer thickness of approximately 5-50 nm may be provided with a high degree of uniformity, as discussed above, which may thus enable reliably preserved integrity of the solder balls without unduly producing undesired material residues during a subsequent reflow or solder process.

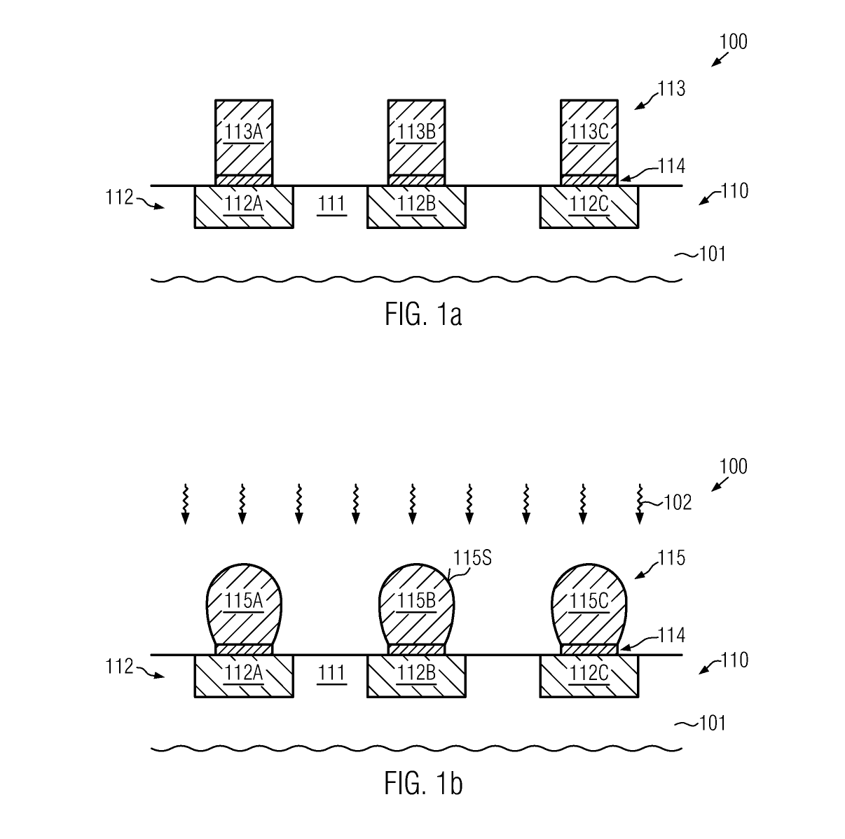

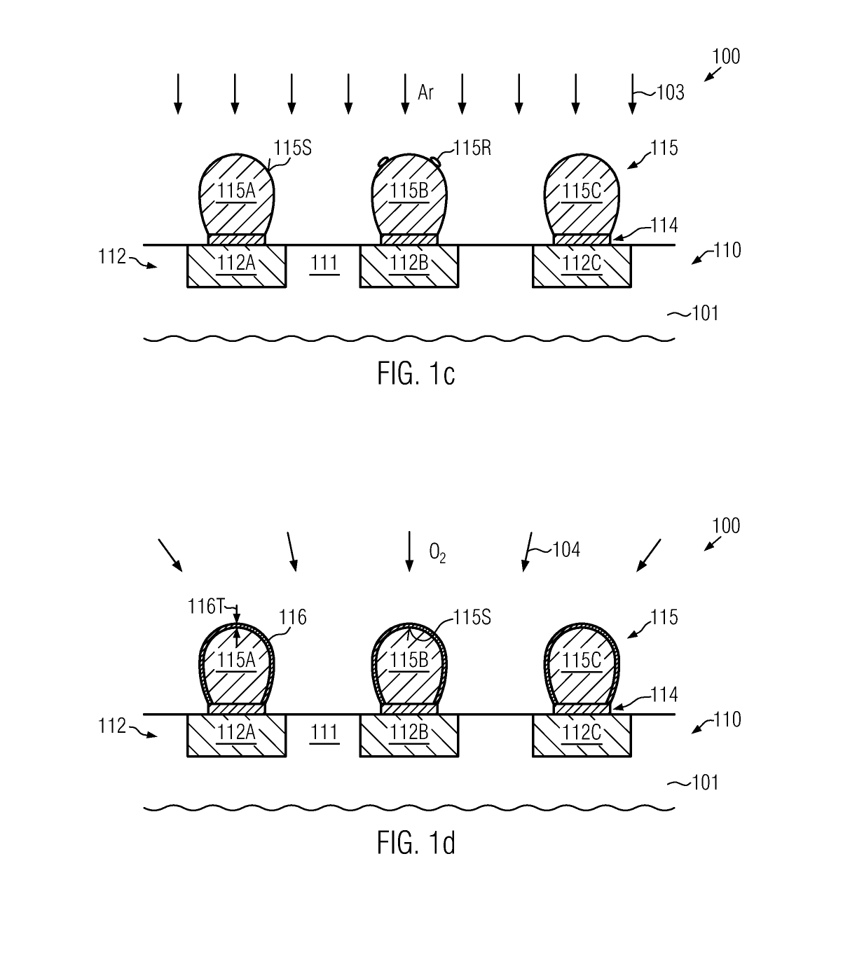

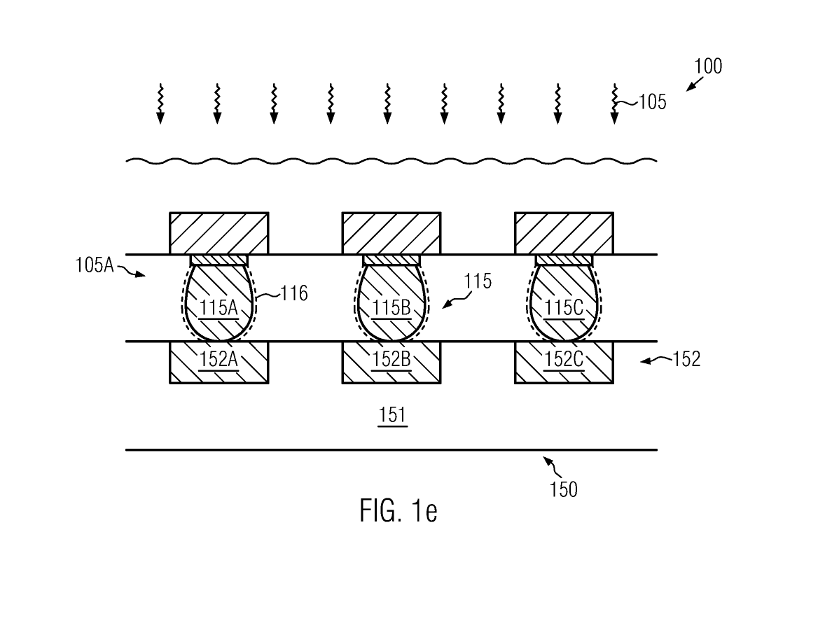

FIG. 1a schematically illustrates a cross-sectional view of a semiconductor device 100 in an advanced manufacturing stage. As illustrated, the device 100 may comprise a substrate 101 which represents any type of substrate that is appropriate for forming circuit elements of integrated circuits thereon. For example, the substrate 101 may represent a bulk semiconductor substrate having formed thereon an appropriate semiconductor layer for forming therein and thereabove circuit elements, such as transistors, resistors, capacitors and the like. In sophisticated applications, the circuit elements (not shown) may be formed on the basis of critical dimensions of 50 nm and less, for instance with respect to the gate length of planar field effect transistors, wherein it should be appreciated, however, that the principles disclosed herein may also be applied to any microstructure devices in which a reliable connection to the package substrate by means of a reflow process is required. In other cases, the substrate 101 may represent a silicon-on-insulator (SOI) substrate including a buried insulating material layer (not shown), while in still other cases the substrate may represent any insulating material having formed thereon an appropriate semiconductor material in amorphous or crystalline form. The semiconductor device 100 may further comprise a metallization system 110 formed above the substrate 101, wherein the metallization system 110 may have any appropriate configuration as is required for connecting the individual circuit elements formed in and above the substrate 101. For example, the metallization system 110 may typically comprise one or more metallization layers formed on the basis of appropriate dielectric materials and metals, such as aluminum, copper and the like. For convenience, the metallization layer 110 is illustrated so as to comprise a dielectric material 111 in which a plurality of metal regions 112, such as regions 112A, 112B, 112C, may be provided so as to connect to any underlying metal lines and vias (not shown). Furthermore, at least a portion of the metal regions 112 may be used so as to carry corresponding contact elements 113 or solder bumps, which may be positioned on the metal regions 112 on the basis of an appropriate under-bump metallization system 114, which in turn may be comprised of one or more dedicated material layers. For example, the under-bump metallization 114 may be comprised of titanium, copper, nickel and the like, wherein these materials may be provided as a combination of materials and/or dedicated materials of different composition may be provided. The contact elements 113 may represent any appropriate metal features, which may comprise at least a certain amount of a solder material, such as a lead-containing solder material and, in other illustrative embodiments, in the form of a lead-free solder material. For example, the elements 113 may be provided in the form of solder bumps, i.e., of metal elements having any appropriate lateral size and a desired height, which may be formed of a substantially homogeneous blend of materials, such as tin and silver, tin and copper, and the like. In other cases, the solder material of the elements 113 may be provided in a part of the elements 113 only, for instance at an upper portion (not shown), while the remaining part of the elements 113 may be comprised of a non-solder material, i.e., of a metal-containing material having a melting point well above 300° C. The dimensions and the pitch between the contact elements 113 is substantially determined by device requirements, wherein, in sophisticated applications, a lateral dimension of the elements 113 may range from several micrometers to several hundred micrometers and more, while the pitch between the solder bumps or elements 113 may be approximately 100 micrometers or significantly less in densely packed device areas.

A process flow for forming the semiconductor device 100 as shown in FIG. 1a may comprise basically the same process techniques as described above. That is, after forming circuit elements and the metallization system 110, which may be accomplished on the basis of any well-established process techniques, the under-bump metallization 114 may be formed on the dielectric material 111 and the metal region 112, while in other cases an additional dielectric passivation layer (not shown) may be provided above the dielectric material 111. Thereafter, an appropriate deposition mask, such as a resist mask and the like, may be provided so as to define the lateral size and position of the elements 113. Next, an appropriate deposition process may be performed, such as an electroplating process, in which the corresponding openings in the mask may be filled up to a desired height level with a solder material. Subsequently, the mask material may be removed and the under-bump metallization 114 may be patterned in accordance with any well-established wet chemical etch recipes, plasma assisted etch recipes and the like. It should be appreciated that a certain degree of under-etching may occur when using isotropic etch recipes for patterning the under-bump metallization 114 by using the contact elements 113 as an etch mask.

FIG. 1b schematically illustrates the semiconductor device 100 in a further advanced manufacturing stage. The semiconductor device 100 may be exposed to a process ambient 102 in which elevated temperatures may be applied so as to reflow at least a portion of the contact elements 113 that is comprised of a solder material. In the embodiment shown in FIG. 1b, the elements 113 (FIG. 1a) may be comprised of a homogenous solder material, which may thus be melted so as to form corresponding solder balls 115, such as solder balls 115A, 115B, 115C. In one illustrative embodiment, the ambient 102 may be established on the basis of an inert process atmosphere, for instance comprising hydrogen or a mixture of hydrogen and nitrogen, or any other inert gas ambient, so as to avoid undue chemical reactions at a surface 115S of the solder balls 115. For example, the ambient 102 may be established with a reduced oxygen content so as to avoid undue oxidation of the surface areas 115S. For example, in some illustrative embodiments, the oxygen contents may be less than approximately 100 parts per million (ppm). To this end, the ambient 102 may be established by using one or more purge steps prior to establishing the elevated temperature in order to reduce the oxygen contents to a desired amount. The temperature during the process 102 may be adjusted to a temperature of 250-350° C. and higher, depending on the melting temperature of the solder material under consideration.

FIG. 1c schematically illustrates the semiconductor device 100 in a further advanced stage in which, according to some illustrative embodiments, a reactive process atmosphere 103 may be established on the basis of a plasma in order to “condition” the surface areas 115S of the solder balls 115. The ambient 103 may be established in some illustrative embodiments on the basis of an appropriate gas component, such as argon, and on the basis of process parameters in order to remove any undesired material residues, as indicated by 115R, which may have been formed on surface areas 115S during the preceding processing, such as the process 102 (FIG. 1b), or during any subsequent processes and substrate handling activities, for instance caused by a contact with oxygen and the like.

In one illustrative embodiment, the plasma-based process 103 may be formed on the basis of the following process parameter values. A pressure of the atmosphere 103 may be established to be 1×10⁻⁴-1×10⁻² mbar (0.01-1 Pa). For example, an appropriate value may be about 6×10⁻⁴ mbar. The ambient 103 may be established by using argon as a process gas in any appropriate process tool which enables establishing a plasma ambient. For example, a plurality of plasma etch tools are available, for instance for processing substrates having a diameter of 200 mm, 300 mm and the like. As is well known, process gases may be supplied to a corresponding process chamber by controlling the gas flow rate, thereby establishing a certain gas concentration within the process chamber, which may thus be determined by the volume of the process chamber and the resulting pressure established therein. For example, for a process chamber appropriate for processing 300 mm substrates, a flow rate of 2-20 sccm (standard cubic centimeter per minute) may be used, wherein an example may be approximately 7 sccm. Moreover, the RF (radio frequency) power for creating a plasma in the ambient 103 may be adjusted to 30-2000 W, wherein, in one example, approximately 1000 W may be selected. Similarly, a low frequency power may be applied, for instance in the range of approximately 20-1250 W, in order to appropriately adjust the ion bombardment, wherein, in one example, approximately 1000 W may be applied. Furthermore, the temperature of the semiconductor device 100 may be adjusted to any value between 0° C. and any value below the melting temperature of the solder material of the solder balls 115.

It should be appreciated that, based on the above-specified parameter values, any other appropriate parameter setting may be determined for any process tool in order to obtain the desired conditioning effect of the treatment 103. For example, for the above-specified parameter values, a process time of 5-105 seconds, for instance in one example 55 seconds, may be used.

FIG. 1d schematically illustrates the semiconductor device 100 according to illustrative embodiments in which a further plasma treatment 104 may be applied in order to form a passivation layer 116 on exposed surface areas of the solder balls 115. In one illustrative embodiment, the plasma treatment 104 may be performed in combination with the plasma process 103 of FIG. 1c in order to appropriately prepare or condition the surface areas 115S of the solder balls 115, as discussed above.

In other illustrative embodiments, the plasma treatment 104 may be performed without a preceding plasma treatment, such as the treatment 103 of FIG. 1c, depending on the process history. For example, as previously discussed, the formation of any material residues may be significantly reduced upon appropriately selecting the process conditions during the formation of the solder balls 115. The plasma treatment 104 may be formed on the basis of an oxygen plasma, thereby initiating an oxidation of the exposed surface areas 115S, thereby forming a corresponding passivation layer 116. That is, upon using an oxygen plasma, an oxide layer may be provided, wherein the well-controllable process conditions during the process 104, and possibly during the process 103 of FIG. 1c, may result in superior uniformity of the characteristics of the passivation layer 116. That is, the material composition may be very homogeneous and also the resulting layer thickness, indicated by 116T, may be very uniform across the semiconductor device 100. In some illustrative embodiments, the passivation layer 116 may be provided in the form of an oxide layer having a thickness of 5-50 nm, wherein a thickness variation of the layer 116 within a single solder ball 115 and across the plurality of solder balls of the device 100 may be approximately 10 percent or less. In some variants, the thickness 116T may be adjusted to approximately 10 nm and less.

The plasma process 104 may be established on the basis of the following parameter settings. The pressure may be set to a range of 1×10⁻⁴-1×10⁻² mbar, for instance a value of approximately 6×10⁻⁴ mbar may be used. An oxygen gas flow may be established on the basis of 2-20 sccm, for instance a value of approximately 12 sccm may be used. The plasma may be generated on the basis of a radio frequency power in the range of 20-1250 W, for instance by using approximately 1000 W. With these parameters, a process time of approximately 60-600 seconds, for instance in one example a process time of approximately 240 seconds, may be applied in order to obtain the layer 116 as an oxide layer having a thickness as specified above.

It should be appreciated that these parameter settings may be readily adapted to any type of process tool used for establishing the plasma ambient for the process 104. Moreover, the processes 103, 104, if both are applied, may be performed in the same process tool, thereby providing an efficient overall process flow.

It should be appreciated that the passivation layer 116 may be formed on the basis of other atomic species, for instance in addition to or alternatively to oxygen, as long as the corresponding resulting passivation material may be removed on the basis of elevated temperatures and an appropriate chemical agent, such as a flux material, in a final soldering process. For example, nitrogen may be incorporated into the layer 116, for instance in addition to providing the oxygen species, thereby increasing the overall robustness of the layer 116, even for a reduced layer thickness.

FIG. 1e schematically illustrates the semiconductor device 100 in a further advanced manufacturing stage. That is, after providing the passivation layer 116, any further processes, such as substrate transport to other manufacturing facilities, the dicing of the substrate 101 into the individual semiconductor chips and the like, may be performed in the presence of the passivation layer 116, thereby achieving superior integrity of the solder balls 115. At any appropriate phase, the device 100 may be connected to a package or carrier substrate 150, which may comprise a plurality of solder pads 152 or any other contact elements, which may be dimensioned and positioned so as to be “complementary” with respect to the solder balls 115. For example, the solder pads or elements 152A, 152B, 152C of the substrate 150 are appropriately configured in order to be connected to the corresponding solder balls 115A, 115B, 115C. Upon connecting the semiconductor device 100 and the package or carrier substrate 150, a solder process 105 may be performed in order to reflow the solder balls 115 and to form an inter-metallic connection with the corresponding solder pads 152. During the process 105, a flux material 105A, such as any commercially available flux material, may be applied, which may thus remove the material of the passivation layer 116, wherein, due to the superior uniformity thereof, a substantially complete removal may be accomplished, thereby providing a reliable connection between the solder balls 115 and the solder pads 152.

As a result, the present disclosure provides manufacturing techniques in which a uniform and thin passivation layer may be formed on solder balls or any other contact elements after the reflow of a solder material, such as a lead-free solder material, wherein the passivation layer may be formed on the basis of a plasma treatment, such as an oxygen plasma treatment. Due to the superior uniformity with respect to material composition and layer thickness, the passivation layer may be efficiently removed during a final soldering process on the basis of flux materials and the like, thereby ensuring a reliable inter-metallic connection between the solder balls and the solder pads of the carrier or package substrate. For example, the passivation layer may be provided in the form of an oxide layer having a thickness of approximately 10 nm and less, wherein also a thickness of up to 50 nm may be provided with high uniformity if necessary in view of process requirements.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a plurality of solder bumps above a substrate;
forming solder balls by reflowing the plurality of solder bumps; and
forming an oxide layer on exposed surface areas of said solder balls by exposing said solder balls to an oxygen-containing plasma atmosphere.

2. The method of claim 1, wherein forming said solder bumps comprises using a lead-free solder material.

3. The method of claim 1, wherein said oxygen-containing plasma atmosphere is established at a pressure of 1×10⁻² mBar or less.

4. The method of claim 3, wherein said oxygen-containing plasma atmosphere is established at pressure of 1×10⁻⁴ mBar or greater.

5. The method of claim 1, further comprising exposing said solder balls to an etch ambient prior to exposing said solder balls to said oxygen-containing plasma atmosphere.

6. The method of claim 5, wherein said etch ambient is established by forming an argon-containing plasma.

7. The method of claim 5, wherein said argon-containing plasma is established at a pressure of 1×10⁻² mBar or less.

8. The method of claim 7, wherein said argon-containing plasma is established at a pressure of 1×10⁻⁴ mBar or greater.

9. The method of claim 1, wherein said oxide layer is formed with a thickness of 5-50 nm.

10. The method of claim 9, wherein said oxide layer is formed with a thickness of 10 nm or less.

11. The method of claim 1, wherein said solder balls are exposed to said oxygen-containing plasma atmosphere for a time of 60-600 seconds.

12. The method of claim 11, wherein said solder balls are exposed to said oxygen-containing plasma atmosphere for a time of 200-300 seconds.

13. The method of claim 5, wherein said solder balls are exposed to said etch ambient for a time of 5-105 seconds.

14. The method of claim 1, wherein said solder bumps are formed from at least one of tin, silver and copper.

15. A method of passivating lead-free solder balls in a semiconductor device, the method comprising:
providing a plurality of said lead-free solder balls so as to have an exposed surface area; and
forming a passivation layer on said exposed surface area with a thickness of approximately 50 nm or less by performing a plasma treatment using an oxygen-containing plasma atmosphere.

16. The method of claim 15, further comprising treating said exposed surface area in plasma based etch ambient prior to performing said plasma treatment.

17. The method of claim 15, further comprising connecting said semiconductor device to a package substrate by reflowing said solder balls in the presence of said passivation layer.

18. The method of claim 15, wherein forming said passivation layer comprises controlling at least one process parameter of said plasma treatment so as to obtain said thickness in a range of approximately 5-10 nm.

19. A method, comprising:
forming a plurality of contact elements in a metallization system of a semiconductor device on the basis of lead-free materials, said contact elements configured to connect to a package substrate;
forming a passivation layer on any exposed surface areas of said contact elements by exposing said contact elements to a plasma atmosphere; and
connecting each of said contact elements including said passivation layer to a contact structure formed on said package substrate by reflowing at least a portion of said contact elements.

20. The method of claim 19, wherein said plasma atmosphere is established by using oxygen.
